(19) United States
(12) Patent Application Publication
(10) Pub. No.: US 2009/0302390 A1
(43) Pub. Date: Dec. 10, 2009

(54) METHOD OF MANUFACTURING SEMICONDUCTOR DEVICE WITH DIFFERENT METALLIC GATES

(75) Inventors: Marcus Johannes Henricus Van Dal, Heverlee (BE); Robert James Pascoe Lander, Leuven (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/066,714

(22) PCT Filed: Sep. 11, 2006
(86) PCT No.: PCT/IB2006/053203

§ 371 Date: Jan. 20, 2009

(30) Foreign Application Priority Data
Sep. 15, 2005 (EP) 05108498.6

(51) Int. Cl. H01L 27/092; H01L 21/8238

(52) U.S. Cl. 257/369; 438/199; 257/E21.632; 257/E27.062

(57) ABSTRACT

A method is described for forming gate structures with different metals on a single substrate. A thin semiconductor cap (26) is formed over gate dielectric (24) and patterned to be present in a first region (16) not a second region (18). Then, metal (30) and a second cap (34) is deposited and patterned to be present in the second region not the first. A thick selectively etchable layer for example of SIGe is deposited, the gates are patterned in both first and second regions, and the selectively etchable layer is removed. A metal layer is deposited and reacted with the first and second caps to form fully suicided or fully germanided layers.

The invention relates to a method of manufacturing a semiconductor device with two different gate materials, and a semiconductor device made by the method.

At present, most gates used in metal oxide semiconductor field effect transistor (MOSFET) type devices are polysilicon (poly). However, future MOSFETs may require the use of a metal gate electrode to eliminate poly-gate depletion effects, which are particularly prevalent with thin gate oxides.

However, the use of a metal gate electrode makes it difficult to achieve a low threshold voltage, since the work function of the metal is not readily matched to that of n-type or p-type silicon. The problem is particularly acute for CMOS circuits, which need gates with differing work functions for the nMOSFET and the PMOSFET devices.

A likely way of achieving CMOS metal gates is to use two different metals for the different gates. However, this requires patterning of one metal prior to deposition of the second metal. Such patterning can seriously impact the quality of the gate dielectric at the locations where the second metal is to be deposited, with a consequent deterioration in the quality of the device.

Removing the dielectric and reforming it in the presence of the first metal is generally undesirable, especially when carried out in an ultra-clean furnace.

An alternative approach is to use a fully silicided (FUSI) gate which has the advantage for dielectric quality that a metallic gate is formed for both NMOS and PMOS from a single deposited polysilicon layer. Unfortunately, such FUSI gates do not meet all the work function and material requirements for both PMOS and NMOS.

US-2004/0132271 describes a method of forming a pair of gates, one of poly and one of silicide. In this process, a polysilicon layer is formed, a mask applied over one of the PMOS and NMOS regions, and then metal is deposited over the other of the PMOS and NMOS region, which remains exposed, and reacted with the polysilicon to form silicide. Then, the mask is removed, a polysilicon layer applied over the whole surface, and the result patterned to form a polysilicon gate in the region that was protected by the mask during the silicidation steps and a silicide gate in the region that was silicided.

A further approach is taught in US-2004/0099916. In this approach, a polysilicon layer is formed over the gate dielectric. A metal layer is then formed over the whole surface, and the metal layer is then patterned so that it is only present over one of the PMOS and NMOS transistor regions. Silicide is then formed over one of the regions, before the gates are patterned.

Neither of these processes forms two metallic gates, since one of the gates is polysilicon in both processes. Note that silicided gates will be referred to as “metallic”. The term “metal” will be used to refer to metal, metal alloy or doped metal layers; such layers are of course “metallic” as well as “metal”.

An alternative process which does provide two different gates of metal silicide is taught by U.S. Pat. No. 6,846,734 which forms fully silicided gates for both PMOS and NMOS transistors with different threshold voltages. Unfortunately, the process is very complicated, and both of the gates are of metal silicide—the process cannot be used to form a simple as-deposited metal gate.

There thus remains a need for an improved process for the manufacture of a pair of metallic gates.

According to the invention there is provided a method of manufacturing a semiconductor device, comprising the steps of:

depositing gate dielectric over the first major surface of a semiconductor body;

forming a first semiconductor cap over the gate dielectric in a first region of the semiconductor body leaving the gate dielectric exposed in a second region;

depositing a metallic layer over the exposed gate dielectric in the second region and over the semiconductor cap in the first region;

depositing a second semiconductor cap over the metallic layer;

etching away the metallic layer and the second semiconductor cap in the first region leaving the metallic layer and the second semiconductor cap in the second region;

depositing a selectively etchable layer over the first and second regions;

patterning the at least one selectively etchable layer, the metallic layer and the first and second semiconductor cap layers to form a first gate pattern in the first region and a second gate pattern in the second region;

selectively etching away the selectively etchable layer;

depositing a reaction metal; and

reacting the reaction metal with the full thickness of the first and second semiconductor cap layers.

In a preferred embodiment, the steps are carried out in exactly the order they are presented. However, this is not essential and it will be appreciated that some variation in the order of these steps is possible. For example, the second semiconductor cap and metallic layer need not necessarily be removed from the first region immediately after deposition, and if required this step could be carried out after patterning the gates.

The method delivers a pair of metallic gates. The first gate has the fully silicided layers above the metallic layer and the second gate just has the fully silicided layer. The invention delivers a transistor in which the gate layer adjacent to the gate dielectric is a fully silicided layer for one gate and a deposited metallic layer for the other gate. Thus, any suitable choice of deposited metal thickness and material is possible for the deposited metallic layer, allowing for great flexibility of manufacturing method.

The use of a selectively etchable layer enables the simultaneous silicidation/germanidation of the source/drain areas and gates.

Conveniently, the selectively etchable layer is a SiGe layer which may be etched by an Ammonia/peroxide mixture wet etch. The layer thickness may be in the range 30 to 150 nm, preferably 50 to 120 nm.

In another aspect, the invention relates to a semiconductor device, comprising:

a semiconductor body having a first major surface;

a first region and a second region;

at least one transistor in the first region and at least one transistor in the second region at the first major surface of the semiconductor body, the transistors in the first and second regions having like gate dielectrics, like source and drain regions and like source and drain contacts;

wherein the at least one transistor in the first region has a fully silicided or germanided gate; and

the at least one transistor in the second region has a gate in the form of a fully silicided gate structure above a metallic layer.

For a better understanding of the invention, embodiments will now be described, purely by way of example, with reference to the accompanying drawings, in which:

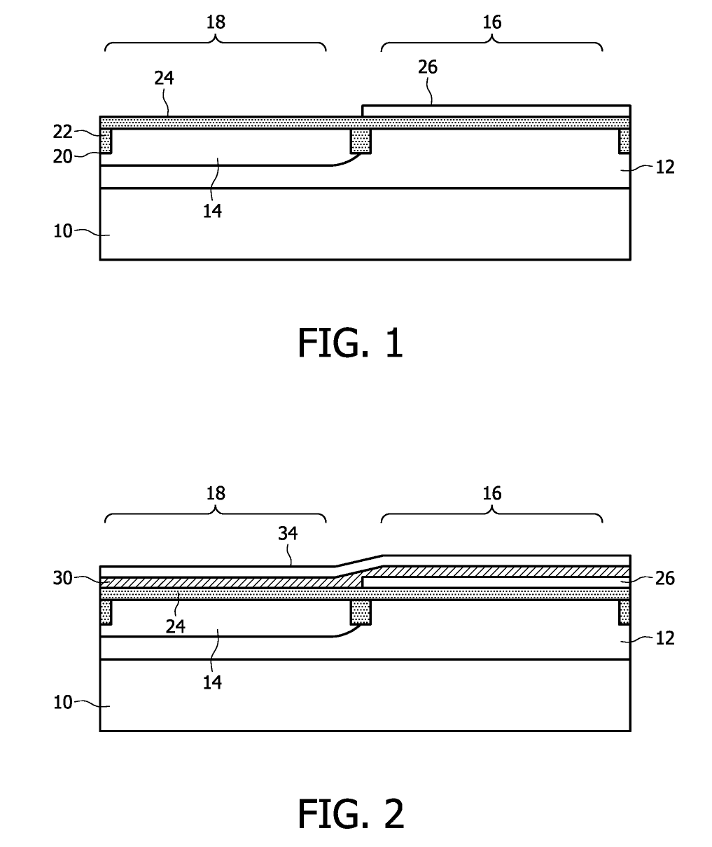

FIGS. 1 to 7 show steps of a method according to a first embodiment of the invention; and

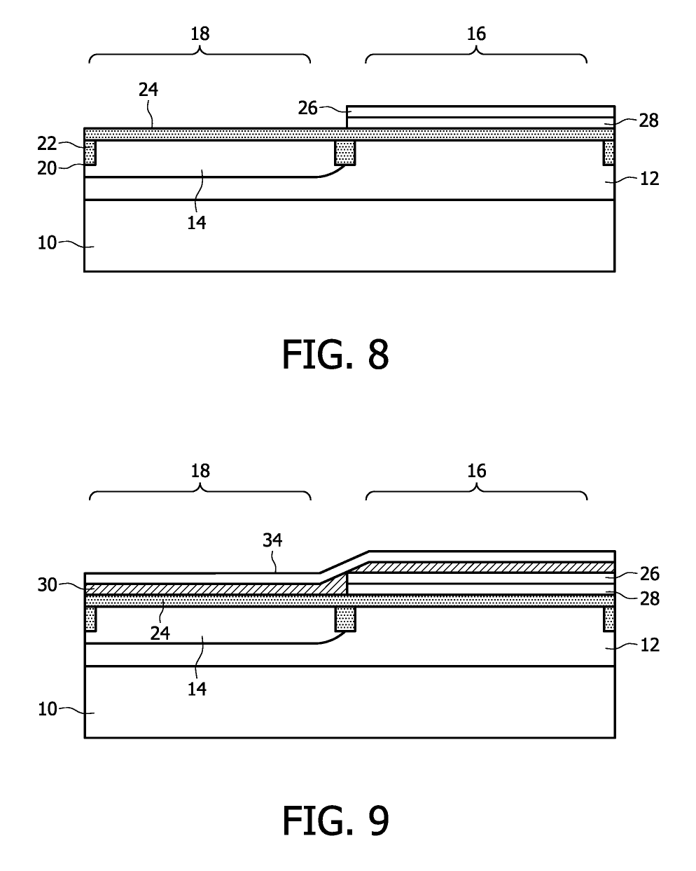

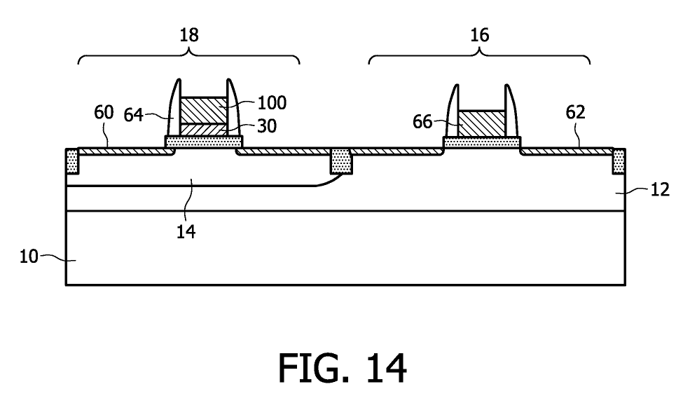

FIGS. 8 to 14 show steps of a method according to a second embodiment of the invention.

Like or similar components are given the same reference numerals in the different figures.

Referring to FIGS. 1 to 7, a first embodiment of the method according to the invention uses an n+ type substrate 10. The first embodiment delivers a PMOS deposited metal gate and an NMOS FUSI gate.

An n-type epitaxial layer 12 is then formed and a p-type body diffusion 14 is implanted over part of the surface. The part of the surface that remains n-type will be referred to the first region 16 in the following and the part of the surface that is rendered p-type will be referred to as the second region 18. In the final structure, the first region 16 and the second region 18 are used to form complementary transistors.

Insulated trenches 20 are formed and filled with silicon dioxide 22 to separate the regions.

Next, a thin gate dielectric 24 is grown over the whole of the surface, and a thin poly-silicon (poly) cap 26 is formed over the gate dielectric 24 in the first region 16 but not the second 18. The gate dielectric can be of any suitable material, for example SiO₂, SiON or a high-k (high dielectric constant) gate dielectric.

Conveniently, the thin cap 26 is at least 5 nm, to protect the dielectric from the etch used to etch away metal 30, but thin enough to avoid topographic issues for lithography, preferably less than 50 nm, further preferably less than 20 nm. In the specific embodiment described the poly layer is 10 nm thick.

Preferably, the poly 26 may be patterned by photolithography in a manner known to those skilled in the art, for example by depositing the poly over the whole surface, defining a photolithographic pattern in photoresist over the first region, etching away the exposed poly in the second region, and stripping the resist.

In the embodiment, the poly is etched away using a wet etch which causes reduced damage to gate dielectric 24.

In an alternative embodiment (not shown), the gate dielectric 24 in the first region is removed and reformed during these steps.

In either approach, this results in the structure shown in FIG. 1.

Next, a metallic layer 30 is deposited over the whole surface. In this embodiment, the metallic layer 30 is of molybdenum oxide. A silicon cap 34 is then deposited over the top; in the embodiment this is of polysilicon. A hard mask can also optionally be deposited at this stage if required for the subsequent steps.

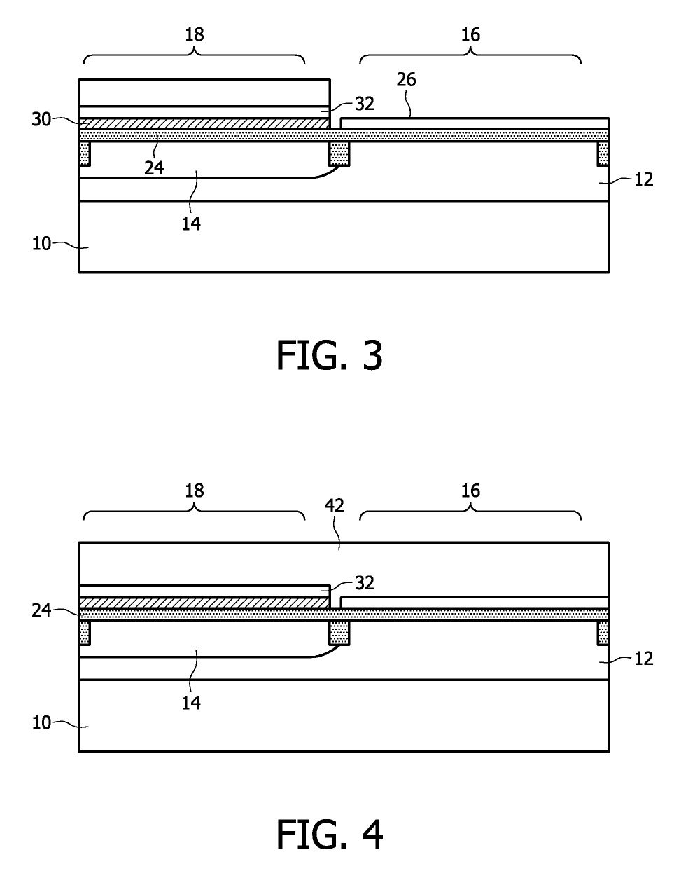

Photoresist 32 is then formed and patterned in the second region 18 and the metallic layer 30 and silicon cap 34 removed in the regions without photoresist, namely first region 16, leaving the metallic layer 30 and silicon cap 34 in the second region 18 as shown in FIG. 3.

The photoresist 32 is removed and a thick silicon germanium layer 42 deposited over the surface, resulting in the structure of FIG. 4.

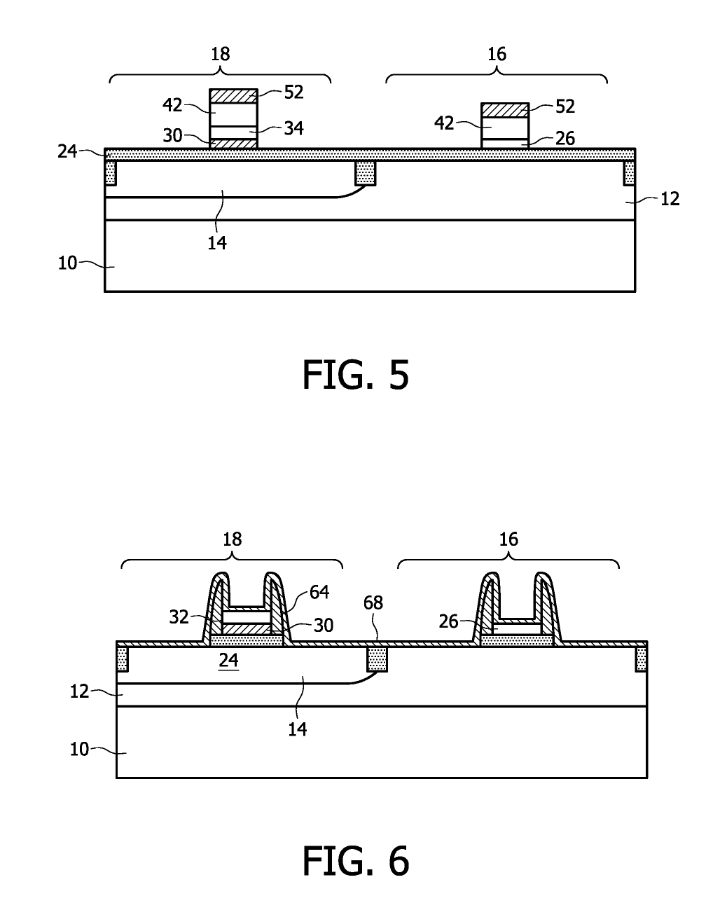

Next, a single patterning step is used to define the gates in both the first and second regions. The use of a single patterning step requires the use only of a single mask, avoiding the need for additional masks. The etch step removes metallic layer 30, silicon cap 34 and the silicon germanium 42 in the second region 18 and the silicon layer 26 and silicon germanium 42 in the first region, except where covered by hard mask 52 which is formed in a conventional way. The etch is selected to stop on the dielectric, as illustrated in FIG. 5.

Sidewall spacers 62 are then formed, the gate dielectric 24 removed except under the gate and the hard mask 52 and the Silicon Germanium 42 removed by selective etching. A Ni(Yb) metallic layer 68 is deposited over the surface.

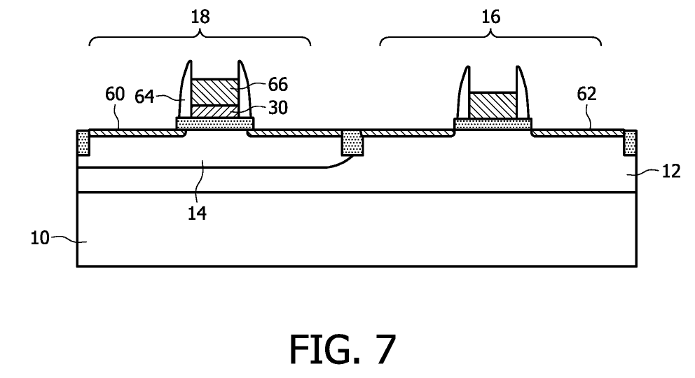

Then a two step Ni(Yb) self-aligned silicidation (saliciation) process is carried out, by processing using a rapid thermal process, a selective etch, and then a further rapid thermal process, to react the Ni(Yb) layer 68 with the underlying silicon to deliver the structure shown in FIG. 7 with Ni(Yb)Si source 60 and drain 62 contacts and a fully silicided Ni(Yb)Si gate 66. It will be noticed that the embodiment uses a self-aligned process (Salicide) though a non-self aligned process can alternatively be used if required.

This leads to the device as illustrated in FIG. 7. Note that the device is then finished as is known to those skilled in the art, by adding contacts, gate, source and drain metallisations, etc.

It may be seen that in the second region 18 the metal 30 is above the gate dielectric but in the first region it is the fully silicided region. Thus using the method according to the invention it is straightforward to provide one gate of deposited metal, here MoO, and the other gate fully silicided.

A second embodiment of the invention will be described with reference to FIGS. 8 to 14. In this embodiment, the fully silicided gate is used for the PMOS transistor and the NMOS gate is deposited metal.

In the embodiment, the epitaxial layer 12 is p-type and the well 14 is n-type.

The process uses the same steps as the process of the first embodiment up to the step of depositing the gate dielectric 24. Then, a thin layer of germanium 28 (Ge) is deposited before depositing the polysilicon 26. These are then etched away from the second region 18 using a wet etch to cause as little damage to the gate dielectric 24 as possible.

Optionally, the gate dielectric 24 may be removed and regrown immediately after etching away the germanium and polysilicon.

Next, a deposited metallic layer 30 is deposited over the whole surface, in the embodiment of tantalum carbide (TaC), followed by silicon cap 34. This leads to the structure of FIG. 9.

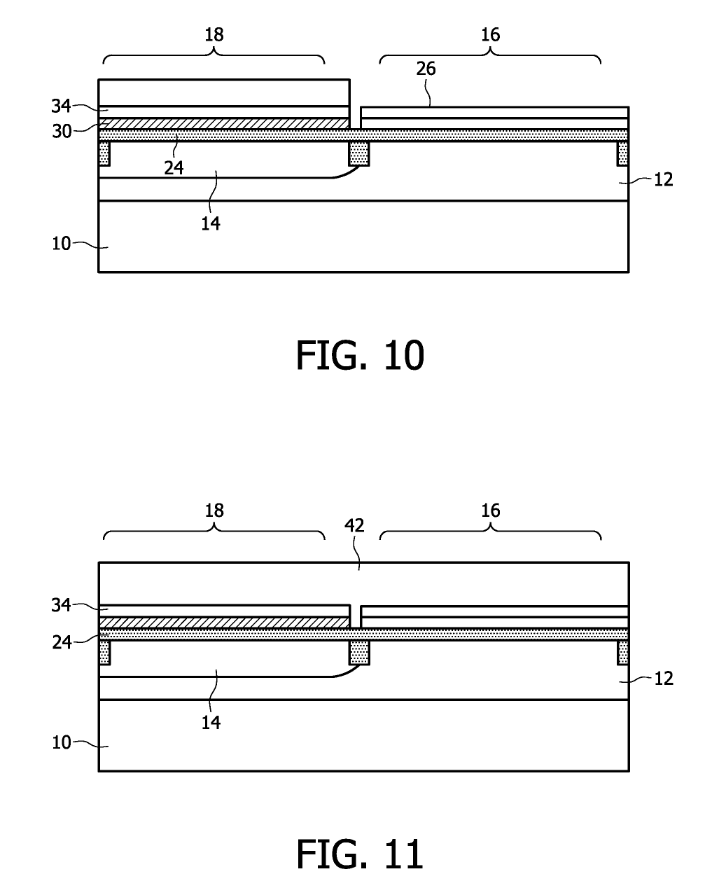

Photoresist 32 is patterned to protect the second region 18 and used as a mask in an etch process which etches away the deposited metallic layer 30 and silicon cap 34 in the first region 16, as shown in FIG. 10.

A thick layer of SiGe alloy is then deposited (FIG. 11).

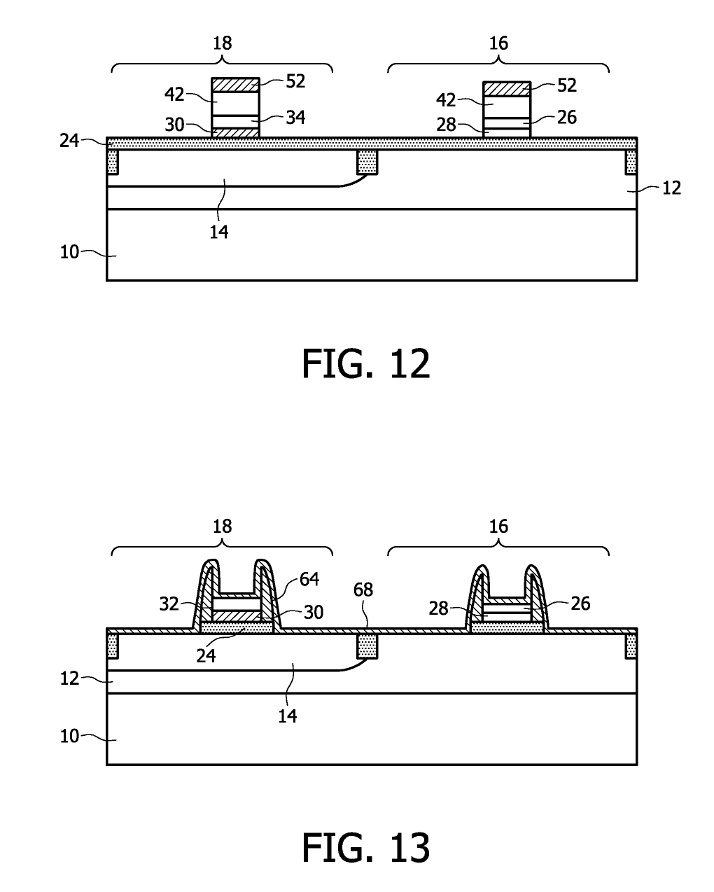

A hard mask 52 is then deposited and patterned and used as a mask to simultaneously etch the gate pattern in the first and second regions 16,18 (FIG. 12). The gate pattern is etched as far as gate dielectric 24.

Spacers 64 are then formed and the silicon germanium removed by a selective etch. A reactive metallic layer 68 of Ni(Yb) is then deposited to result in the structure of FIG. 13.

A two-step Ni self-aligned siliciding (salicidation) step using the deposited layer 68 of Ni is then used as in the first embodiment to form source and drain contact regions 60,62 and to form a fully silicided gate 66 in the first region by the reaction of the Ni top layer with the silicon cap 26, and by reaction of the Ni deposited layer with the Germanium layer 34 in the second region, forming fully silicided/germanided gate 100 in the first region.

In practice, it is likely that the presence of both a silicon poly layer 26 and a germanium layer 34 will mean that the fully silicided/germanided gate 100 includes a layer of NiSi and a layer of NiSiGe, which is perfectly acceptable.

It will be appreciated by those skilled in the art that either a fully silicided or fully germanided gate may be provided in either of the first or second region by suitable choice of deposited silicon or germanium layers as the first semiconductor cap layer 26 and second semiconductor cap layer 34. If required, different semiconductors may be used, as in the second embodiment, to provide different gate materials in the first and second regions.

Those skilled in the art will realise that there are many alternatives that may be used. Any suitable materials may be used, either for the metals or the semiconductors. For example, some of the silicon layers may be replaced with germanium which also reacts with metal. The body may include separate p-type and n-type wells, a p-type well formed within an n-type body or vice versa, or any suitable combination.

The choice of metal used to silicide (or germanide) the gate may be selected as required. For example, the p-type transisor may include a Pt rich fully silicided layer instead of the Ni(Si)Ge layer formed in the second embodiment.

Example choices for the deposited metal 30 include TaC, Mo(Te), TaN, Ta-rich N, WN, or W with implants (for example Te or Se) all of which would be suitable for an n-type transistor.

Indeed, it is a strength of the method that it can be adapted to almost any choice of deposited metal (30).

The method is not restricted to CMOS transistors but may be used wherever two separate gate materials are required.

1. A method of manufacturing a semiconductor device, comprising the steps of:
depositing gate dielectric over the first major surface of a semiconductor body;
forming a first semiconductor cap over the gate dielectric in a first region of the semiconductor body leaving the gate dielectric exposed in a second region;
depositing a metallic layer over the exposed gate dielectric in the second region and over the semiconductor cap in the first region;
depositing a second semiconductor cap over the metallic layer;
etching away the metallic layer and the second semiconductor cap in the first region leaving the metallic layer and the second semiconductor cap in the second region;
depositing a selectively etchable layer over the first and second regions;
patterning the at least one selectively etchable layer the metallic layer and the first and second semiconductor cap layers form a first gate pattern in the first region and a second gate pattern in the second region;
selectively etching away the selectively etchable layer;
depositing a reaction metal; and
reacting the reaction metal with the full thickness of the first and second semiconductor cap layer.

2. A method according to claim 1 wherein the selectively etchable layer is a layer of silicon-germanium deposited to a depth of at least 30 to 150 nm.

3. A method according to claim 1 wherein the thickness of the first semiconductor cap is in the range 5 nm to 50 nm.

4. A method according to claim 1 wherein in the step of reacting the reaction metal the reaction metal reacts with the semiconductor body in the first and second regions to form source and drain contacts.

5. A method according to claim 1 wherein the first major surface of the semiconductor body is a n-type region in the first region and an p-type region the second region.

6. A method according to claim 5 wherein the metallic layer is MoO.

7. A method according to claim 5 wherein the reaction metal layer is Ni(Yb) and the step of reacting the reaction metal layer forms a fully silicided Ni(Yb)Si layer.

8. A method according to claim 1 wherein the first major surface of the semiconductor body is an p-type region in the first region and an n-type region in the second region.

9. A method according to claim 8 wherein the metallic layer is a metal layer of TaC, TaN, or WN, not necessarily in a stochiometric form, W, Ta, Mo, with optional implants of Te or Se.

10. A method according to claim 8 wherein the first semiconductor cap includes a germanium layer, the reaction metal layer is of Ni, and the step of reacting the reaction metal layer reacts the reaction metal layer with the germanium layer and any silicon layer present to form a fully reacted gate layer including germanide.

11. A method according to claim 8 wherein the first semiconductor cap includes a silicon layer, the reaction metal layer includes Pt, and the step of reacting the reaction metal layer forms a fully silicided platinum rich silicide layer.

12. A semiconductor device, comprising
a semiconductor body having a first major surface;
a first region and a second region;
at least one transistor in the first region and at least one transistor in the second region at the first major surface of the semiconductor body, the transistors in the first and second regions having like gate dielectrics, like source and drain regions and like source and drain contacts;
wherein the at least one transistor in the first region has a fully silicided and/or germanided gate; and
the at least one transistor in the second region has a gate in the form of a fully silicided gate structure above a metallic layer.

13. A semiconductor device according to claim 12, wherein the semiconductor body has an n-type region at the first major surface in the first region and a p-type region at the first major surface in the second region,
the gate in the first region is a fully silicided gate of Nickel and silicon; and
the metallic layer is of MoO.

14. A semiconductor device according to claim 12 wherein the semiconductor body has a p-type region at the first major surface in the first region and an n-type region at the first major surface in the second region,
the gate in the first region is a fully germanided gate of nickel and germanium, a fully silicided-germanided gate of nickel silicon and germanium or a platinum rich fully-silicided gate of nickel and silicon; and
the metallic layer is of TaC, TaN, or WN, not necessarily in a stochiometric form, W, Ta, Mo, with optional implants of Te or Se.
